(19) United States
(12) Patent Application Publication
(10) Pub. No.: US 2011/0162711 A1
(43) Pub. Date: Jul. 7, 2011

(54) WAVELENGTH-CONVERTING COMPOSITION AND PHOTOVOLTAIC DEVICE COMPRISING LAYER COMPOSED OF WAVELENGTH-CONVERTING COMPOSITION

(75) Inventors: Takeshi Takeuchi, Hyogo (JP); Takeshi Ito, Hyogo (JP); Yoshihiro Takihana, Hyogo (JP); Wataru Okada, Shizuoka (JP); Yoshiaki Fukunishi, Tokyo (JP)

(73) Assignee: SUMITOMO BAKELITE CO., LTD., Tokyo (JP)

(21) Appl. No.: 12/995,922

(22) PCT Filed: Jun. 4, 2009
(86) PCT No.: PCT/JP2009/060280

§ 371 Date: Feb. 18, 2011

(30) Foreign Application Priority Data
Jun. 6, 2008 (JP) 2008-149503
Aug. 7, 2008 (JP) 2008-204521
Aug. 26, 2008 (JP) 2008-216850
Sep. 10, 2008 (JP) 2008-231887
Sep. 19, 2008 (JP) 2008-241480
Oct. 21, 2008 (JP) 2008-270797
Dec. 17, 2008 (JP) 2008-320648

(51) Int. Cl. H01L 31/0232; F21V 9/00

(52) U.S. Cl. 136/257; 252/582

(57) ABSTRACT

There is provided a wavelength-converting composition and a photovoltaic device in which a wavelength-converting substance can be uniformly dispersed without causing an increase in manufacturing costs. The wavelength-converting composition contains a curing resin and a wavelength-converting substance for converting the wavelength of absorbed light.

### TECHNICAL FIELD

The present invention relates to a wavelength-converting composition that can be suitably used in LED lights, solar cells, bio-imaging, and the like; and particularly a wavelength-converting composition provided to a photovoltaic device and used for converting the wavelength of light and supplying the result to a photovoltaic layer of the photovoltaic device, and to a photovoltaic device comprising a layer composed of the wavelength composition.

### BACKGROUND ART

Photovoltaic devices are used as solar cells for converting sunlight photoelectrically and producing electrical energy. Currently, the mainstream photovoltaic devices of this type are those that use monocrystalline silicon, polycrystalline silicon, spheroidal or amorphous silicon, CdTe, or CIGS in the photovoltaic layers for converting light to electromotive force. Recently, dye-sensitized solar cells and other organic solar cells have also been developed, and a variety of photovoltaic layers containing organic materials have come to be used. In the case of these photovoltaic devices, the spectral sensitivity is roughly limited to the visible light range, and the ultraviolet light range, infrared light range, and other ranges outside of the visible light in the solar rays cannot be efficiently converted into electrical energy. In addition, crystalline silicon solar cells are problematic in that photoelectric conversion efficiency decreases with the increased temperature produced by ultraviolet light absorption. Moreover, organic solar cells using photovoltaic layers that contain organic material are problematic in that the photoelectric conversion efficiency is reduced by the degradation of organic materials caused by ultraviolet rays.

Accordingly, a technique for raising the efficiency of converting light to electrical energy in a photovoltaic device is described in Patent Document 1, wherein a glass plate compounded with europium (Eu³⁺), samarium (Sm²⁺), terbium (Tb²⁺) and other rare-earth ions is provided as a wavelength-converting substance 6 to the light-receiving surface of a photovoltaic layer in a photovoltaic device. The ultraviolet range of solar rays is thereby converted to the visible light range and supplied to the photovoltaic layer.

In addition, it is described in Patent Document 2 that europium (Eu³⁺) is doped as a wavelength-converting substance in a non-reflective membrane provided to the light-receiving surface of a photovoltaic layer in a photovoltaic device. Formation in the non-reflective membrane and injection of the europium (Eu³⁺) are repeated a plurality of times in order to uniformly disperse the europium (Eu³⁺) in the non-reflective membrane in the photovoltaic device. The ultraviolet range of solar rays is thereby converted to the visible light range and supplied to the photovoltaic layer.

Moreover, it is described in Patent Document 3 that CdSe, CdTe, GaN, Si, InP, ZnO and other semiconductor microparticles, as well as particles obtained by forming these microparticles into a core-shell configuration, are used as a wavelength-converting substance.

Methods for synthesizing silicon semiconductor microparticles having comparatively low toxicity among semiconductor microparticles are described in Patent Document 4 (sputtering method), Patent Document 5 (anodic oxidation method), and Non-patent Document 1 (mass production method); and a method for preparing compound microparticles of zinc oxide semiconductor microparticles and silica microparticles by a spray-drying method and a method for synthesizing zinc oxide semiconductor microparticles is described in Patent Document 6.

### PRIOR ART DOCUMENTS

### Patent Documents

Patent Document 1: Japanese Laid-open Patent Publication No. 2003-142716 (paragraphs 0021, 0022; FIG. 1)
Patent Document 2: Japanese Laid-open Patent Publication No. 8-204222 (paragraph 0010; FIG. 1)
Patent Document 3: Japanese Laid-open Patent Publication No. 2006-216560
Patent Document 4: Japanese Laid-open Patent Publication No. 2006-70089
Patent Document 5: Japanese Laid-open Patent Publication No. 6-90019 (paragraph 0009)
Patent Document 6: Japanese Laid-open Patent Publication No. 2003-019427
Non-patent Documents

Non-patent Document 1: Clean Technology, 7, 27-30 (2007)
Non-patent Document 2: J. Appl. Phys., 89(11), 6431-6434 (2001)

### DISCLOSURE OF THE INVENTION

In order to provide a wavelength-converting layer and to improve the efficiency of converting light to electrical energy as described above, wavelength conversion efficiency must be improved without adversely affecting the permeability of light used for photoelectric conversion in the wavelength-converting layer. When the wavelength-converting layer has low transparency, and the light used for photoelectric conversion is blocked, the photoelectric conversion efficiency of the photovoltaic device is reduced rather than increased even in cases in which light that is not used for photoelectric conversion is changed by the wavelength-converting layer to light that can be used for photoelectric conversion. For this reason, a wavelength-converting substance must be uniformly dispersed in the wavelength-converting layer, and the permeability of light used for photoelectric conversion must be prevented from being adversely affected. However, in the photovoltaic device described in Patent Document 1, the wavelength-converting substance may aggregate when the glass substrate is formed, and it becomes difficult to uniformly disperse the wavelength-converting substance. It is therefore impossible to compound an adequate rare-earth ion phosphor; a substance having adequate transparency, ultraviolet ray absorption, and a wavelength-converting function cannot be obtained; and it becomes difficult to sufficiently improve the photoelectric conversion efficiency of the photovoltaic device. It also becomes impossible to focus light on the end surface of a glass substrate in the manner of a solar concentrator and to transmit adequate wavelength-converting light to the photovoltaic layer, making it difficult to adequately improve the photoelectric conversion efficiency of the photovoltaic device. The wavelength-converting substance can be uniformly dispersed to some extent in the photovoltaic device described in Patent Document 2, but formation of the non-reflective membrane layer and injection of the wavelength-converting substance must be repeated a plurality of times, creating problems in that the steps are made more complicated and manufacturing costs are increased. Even in the energy-converting membrane described in Patent Document 3, quantum dots of a wavelength-converting substance that measure several nanometers in size may become aggregated, making it difficult to uniformly disperse the wavelength-converting substance. For this reason, it becomes impossible to compound adequate quantum dots or to obtain an energy-converting membrane having adequate transparency, ultraviolet ray absorption, and wavelength-converting function, and it becomes difficult to adequately improve the photoelectric conversion efficiency of the photovoltaic device.

In view of the foregoing problems, an object of the present invention is to provide a wavelength-converting composition and a photovoltaic device in which a wavelength-converting substance can be uniformly dispersed without causing an increase in manufacturing costs.

### Means for Solving the Problems

A characteristic aspect of the wavelength-converting substance according to the present invention is that the substance comprises a curing resin and a wavelength-converting substance for converting a wavelength of absorbed light.

According to this aspect, the photoelectric conversion efficiency of a photovoltaic device can be improved by including the curing resin and the wavelength-converting substance for converting the wavelength of absorbed light when a wavelength-converting composition is provided, for example, to the substrate of the photovoltaic device or the like. In addition, complicated steps such as those used in the past can be dispensed with because the wavelength-converting composition may merely be provided to the substrate by, for example, coating or the like. As a result, a wavelength-converting composition in which the wavelength-converting substance can be uniformly dispersed can be obtained without causing an increase in manufacturing costs.

In this aspect, oxide microparticles are preferably contained, and the wavelength-converting substance is preferably contained in the oxide microparticles.

According to this aspect, the wavelength-converting substance is contained in the oxide microparticles, whereby the wavelength-varying substance contained in the oxide microparticles can be dispersed with greater uniformity because the oxide microparticles are arranged in a regular structure when the wavelength-converting composition is provided to the substrate.

In this aspect, the oxide microparticles are preferably contained in an amount of 40 to 60 vol %.

According to this aspect, the oxide microparticles are contained in an amount of 40 to 60 vol %, whereby the oxide microparticles can be densely packed and the oxide microparticles are arranged in a regular structure. Light permeability can therefore be maintained even better. In addition, the wavelength-varying substance contained in the oxide microparticles can be dispersed with greater uniformity because the oxide microparticles are arranged in a regular structure. Furthermore, not only is the amount of curing resin in the wavelength-converting layer reduced, but a structure is obtained in which the curing resin is present as fine, thin particles between the oxide microparticles, making it difficult for ultraviolet light and other light harmful to the curing resin to be absorbed by the curing resin, and resulting in better durability.

In this aspect, the oxide microparticles preferably have a mean particle diameter of 20 to 100 nm. A diameter of 45 to 55 nm is more preferred.

The dispersibility and flowability of the oxide microparticles are improved and the wavelength-varying substance contained in the oxide microparticles is dispersed with greater uniformity by keeping the mean particle diameter of the oxide microparticles in the above range.

In this aspect, the oxide microparticles are preferably silica or zirconia microparticles.

The transparency of the oxide microparticles and the wavelength-converting composition can be increased by selecting silica or zirconia as the oxide microparticles. In addition, the light emission efficiency (wavelength conversion efficiency) can be markedly improved and higher durability can be obtained by coating the surface defects of the wavelength-converting substance.

In this aspect, the oxide microparticles are preferably YVO₄ or Y₂O₃ microparticles.

The transparency of the oxide microparticles and the wavelength-converting composition can be increased by selecting YVO₄ or Y₂O₃ as the oxide microparticles. In addition, the light emission efficiency (wavelength conversion efficiency) can be markedly improved and higher durability can be obtained by coating the surface defects of the wavelength-converting substance.

In this aspect, bismuth (Bi) is preferably included.

The absorption wavelength range of the wavelength-converting substance can be changed or broadened by including bismuth (Bi) in the wavelength-converting composition.

In this aspect, the wavelength-converting substance is preferably a substance containing one, or two or more elements selected from the group consisting of europium (Eu), erbium (Er), dysprosium (Dy), and neodymium (Nd).

Solar rays in the ultraviolet range and infrared range can be converted to light in the visible light range by using an above-mentioned substance as the wavelength-converting substance.

In this aspect, the wavelength-converting substance is preferably semiconductor microparticles.

Solar rays in the ultraviolet range and infrared range can be converted to light in the visible light range by using the above-mentioned substance as the wavelength-converting substance.

In this aspect, the semiconductor microparticles are preferably silicon (Si).

Comparatively low toxicity can be obtained and special handling to counteract toxicity, such as that performed in the case of semiconductor particles that contain toxic Cd or the like, can be dispensed with to manufacture and use a wavelength-converting composition in a safe manner by using the above-described substance as the semiconductor microparticles.

In this aspect, the semiconductor microparticles are preferably zinc oxide (ZnO).

Comparatively low toxicity can be obtained and special handling to counteract toxicity, such as that performed in the case of semiconductor particles that contain toxic Cd or the like, can be dispensed with to manufacture and use a wavelength-converting composition in a safe manner by using the above-described substance as the semiconductor microparticles.

An aspect of the wavelength-converting layer according to the present invention is that the layer is formed by curing a layer of the wavelength-converting composition.

The wavelength-varying substance can be uniformly dispersed and the light permeability is not adversely affected. In addition, complicated steps such as those used in the past can be dispensed with because the wavelength-converting composition may merely be provided to the substrate by, for example, coating or the like. As a result, a wavelength-converting layer in which the wavelength-converting substance is uniformly dispersed can be obtained without causing an increase in manufacturing costs.

An aspect of the photovoltaic device according to the present invention is that the above-mentioned photovoltaic device comprises the wavelength-converting layer.

According to this aspect, the permeability of light used by the photovoltaic device for photoelectric conversion is not adversely affected because the oxide microparticles are arranged in a regular structure in the wavelength-converting layer formed in the photovoltaic device. In addition, the wavelength-converting substance contained in the oxide microparticles is uniformly dispersed in the wavelength-converting layer by arranging the oxide microparticles in a regular structure. Furthermore, complicated steps such as those used in the past can be dispensed with because the wavelength-converting composition may merely be provided to the photovoltaic device by, for example, coating and the like, and then cured by light or heat during formation of the wavelength-converting layer. As a result, a photovoltaic device in which the wavelength-converting substance is uniformly dispersed can be obtained without causing an increase in manufacturing costs.

In this aspect, the wavelength-converting layer preferably has a raised and depressed structure in a plane of the photovoltaic device.

According to this aspect, light-transmission loss, reflection loss at the interface of the photovoltaic device and the wavelength-converting layer, and the like can be reduced, and light converted by the wavelength-converting layer can be efficiently supplied to the photovoltaic device.

In this aspect, the raised and depressed structure preferably has a height differential of 300 nm to 100 μm.

According to this aspect, light-transmission loss, reflection loss at the interface of the photovoltaic device and the wavelength-converting layer, and the like can be further reduced, and light converted by the wavelength-converting layer can be more efficiently supplied to the photovoltaic device.

In this aspect, the raised and depressed structure preferably has an in-plane periodicity of 300 nm to 50 μm.

According to this aspect, light-transmission loss, reflection loss at the interface of the photovoltaic device and the wavelength-converting layer, and the like can be further reduced, and light converted by the wavelength-converting layer can be more efficiently supplied to the photovoltaic device.

In this aspect, the raised and depressed structure preferably has an even smaller raised and depressed sub-pattern.

According to this aspect, light-transmission loss, reflection loss at the interface of the photovoltaic device and the wavelength-converting layer, and the like can be further reduced, and light converted by the wavelength-converting layer can be more efficiently supplied to the photovoltaic device.

In this aspect, wavelength-converting layers having two or more different types of raised and depressed structures are laminated.

According to this aspect, light-transmission loss, reflection loss at the interface of the photovoltaic device and the wavelength-converting layer, and the like can be further reduced, and light converted by the wavelength-converting layer can be more efficiently supplied to the photovoltaic device.

In this aspect, the wavelength-converting layer is preferably formed by an inkjet.

According to this aspect, the raised and depressed pattern can be efficiently formed at low cost.

In this aspect, the inkjet is preferably piezo inkjet or electrostatic inkjet.

According to this aspect, the raised and depressed pattern can be more efficiently formed at low cost.

### BRIEF DESCRIPTION OF THE DRAWINGS

FIG. 1 is a view illustrating a photovoltaic device according to the present invention;

FIG. 2 is a view illustrating details of a wavelength-converting layer;

FIG. 3 is a view illustrating another embodiment of the photovoltaic device according to the present invention;

FIG. 4 is a view illustrating another embodiment of the photovoltaic device according to the present invention;

FIG. 5 is a view illustrating an embodiment of a photovoltaic device in which the wavelength-converting layer has a raised and depressed pattern according to the present invention;

FIG. 6 is a view illustrating another embodiment of a photovoltaic device in which the wavelength-converting layer has a raised and depressed pattern according to the present invention;

FIG. 7 is a view illustrating another embodiment of a photovoltaic device in which the wavelength-converting layer has a raised and depressed pattern according to the present invention;

FIG. 8 is a view illustrating another embodiment of a photovoltaic device in which the wavelength-converting layer has a raised and depressed pattern according to the present invention;

FIG. 9 is a view illustrating another embodiment of a photovoltaic device in which the wavelength-converting layer has a raised and depressed pattern according to the present invention; and

FIG. 10 is a view illustrating another embodiment of a photovoltaic device in which the wavelength-converting layer has a raised and depressed pattern according to the present invention.

### BEST MODE FOR CARRYING OUT THE INVENTION

### Embodiment 1

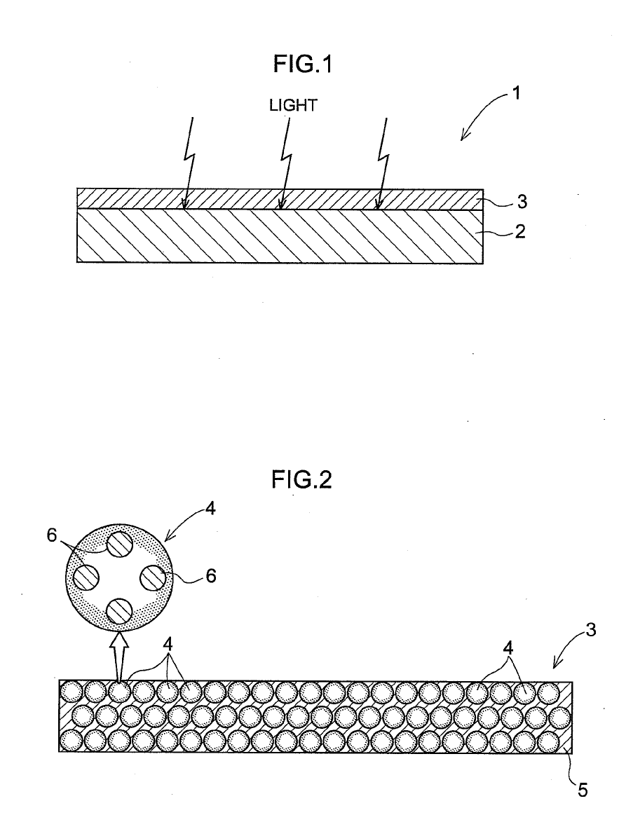

A first embodiment of the present invention will be described below with reference to the drawings. FIG. 1 illustrates a photovoltaic device 1 comprising a wavelength-converting layer 3 formed of a wavelength-converting composition according to the present invention. The photovoltaic device 1 comprises a photovoltaic layer 2 for generating electromotive force using light, and the wavelength-converting layer 3 formed of the wavelength-converting composition is provided to the light-receiving surface of the photovoltaic layer 2.

The photovoltaic layer 2 generates electromotive force using light, and comprises a semiconductor layer composed of a p-type semiconductor layer, a vacuum-semiconductor layer, and an n-type semiconductor layer; an EVA resin composition or other sealing member; and a transparent electrode layer provided to one or both sides of the semiconductor layer. The semiconductor layer is not subject to any particular limitations, and possible examples include monocrystalline silicon, polycrystalline silicon, spheroidal silicon, amorphous silicon, compound semiconductors, organic semiconductors, and quantum dot semiconductors. The transparent electrode is not subject to any particular limitations, and possible examples include ITO and tin oxide. The structure of the photovoltaic device 1 is not subject to any particular limitations, and the wavelength-converting composition of the present invention can be used in a variety of photovoltaic devices 1. In particular, glass, a transparent electrode, a non-reflective layer, a protective layer, or the like may also be formed on the photovoltaic layer 2 in cases in which the wavelength-converting layer 3 is provided to the commercially-available photovoltaic layer 2. In these cases, the wavelength-converting layer 3 is formed above or below the glass, transparent electrode, non-reflective layer, protective layer, and the like. Solar rays in the ultraviolet range are converted to the visible light range by the wavelength-converting layer 3. Accordingly, degradation of the organic materials used in a solar cell can be inhibited, and an increased service life can also be expected.

In this embodiment, solar rays in the ultraviolet range are converted to the visible light range by the wavelength-converting layer 3. As illustrated in FIG. 2, the wavelength-converting layer 3 comprises a light-curing resin 5, oxide microparticles 4 dispersed in the light-curing resin 5, and a wavelength-converting substance 6 dispersed in the oxide microparticles 4. The wavelength-converting layer 3 is formed by, for example, applying the below-described wavelength-converting composition to the surface of the photovoltaic layer 2, and curing the resin with light. The wavelength-converting layer 3 can therefore be formed merely by, for example, applying the wavelength-converting composition to the commercially-available photovoltaic layer 1, and curing the resin with light.

The wavelength-converting composition that constitutes the wavelength-converting layer 3 will be described in detail below. The wavelength-converting composition is constructed including the curing resin 5 and the wavelength-converting substance 6 for converting the wavelength of absorbed light. The wavelength-converting composition is preferably constructed using the curing resin 5 and the oxide microparticles 4 that contain the wavelength-converting substance 6 for converting the wavelength of absorbed light.

A light-curing resin or a heat-curing resin can be used as the curing resin 5, and no particular limitations are imposed on the resin as long as a light-transmitting resin is used. Examples include acrylic resin, epoxy resin, silicone resin, ethylene vinyl acetate (EVA) resin, and the like.

Examples of epoxy resins include bisphenol-A epoxy resins, bisphenol-F epoxy resins, bisphenol-S epoxy resins, naphthalene epoxy resins or hydrogenation products thereof, epoxy resins having a dicyclopentadiene skeleton, epoxy resins having a triglycidyl isocyanurate skeleton, epoxy resins having a cardo skeleton, and epoxy resins having a polysiloxane structure. A resin having an alicyclic structure is preferred when heat resistance must be ensured because, for example, antireflection films or photovoltaic layers composed of amorphous silicon are formed directly. The following alicyclic epoxy resins can be appropriately used, for example: 3,4-epoxycyclohexylmethyl 3′,4′-epoxycyclohexane carboxylate, 1,2,8,9-diepoxylimonene, resins in which 3,4-epoxycyclohexyl methanol and 3,4-epoxycyclohexane carboxylic acid are linked by ester bonds to the two ends of an s-caprolactone oligomer, alicyclic epoxy resins having a hydrogenated bisphenol skeleton and a hydrogenated bisphenol-A skeleton, and the like.

The resin used as the acrylic resin is not subject to any particular limitations as long as the resin is a (meth)acrylate having two or more functional groups. A resin having an alicyclic structure is preferred when heat resistance must be ensured because, for example, antireflection films or photovoltaic layers composed of amorphous silicon are formed directly. In particular, an acrylic resin obtained by polymerizing at least one or more (meth)acrylates selected from Chemical Formulas (1) and (2) is preferred as the (meth)acrylate having an alicyclic structure.

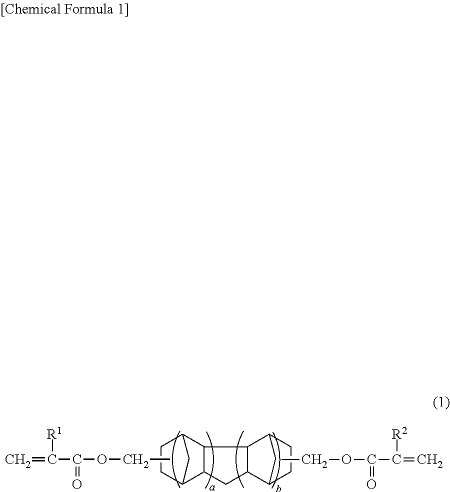

(In Chemical Formula (1), R¹ and R² may be different from each other and are each a hydrogen atom or a methyl group, a is 1 or 2, and b is 0 or 1.)

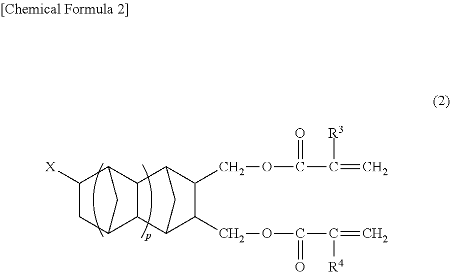

(In General Formula (2), X is H, —CH₃, —CH₂OH, NH₂,

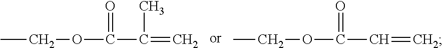

R³ and R⁴ are each H or —CH₃; and P is 0 or 1.)

Furthermore, the resin is preferably at least one or more acrylates selected from among dicyclopentadienyl diacrylates having a structure in which R¹ and R² are hydrogens, a is 1, and b is 0 in Chemical Formula (1), and from among perhydro-1,4,5,8-dimethanonaphthalene-2,3,7-(oxymethyl)triacrylate having a structure in which X is —CH₂OCOCH═CH₂, R³ and R⁴ are hydrogens, and p is 1, as well as acrylates having a structure in which X, R³, and R⁴ are each a hydrogen, and p is 0 or 1 in General Formula (2). Norbornane dimethylol diacrylate having a structure in which X, R³, and R⁴ are each a hydrogen, and p is 0 is the most preferred from the standpoint of viscosity or the like.

A water-dispersed acrylic resin can also be used as the acrylic resin. The term “water-dispersed acrylic resin” refers to an acrylic resin that is an acryl monomer, oligomer, or polymer dispersed in a dispersion medium primarily composed of water, and that is a type of acrylic resin in which a cross-linking reaction proceeds only slightly in a diluted state such as an aqueous dispersion, but the cross-linking reaction proceeds and solidification occurs even at normal temperature when the water is vaporized; or an acrylic resin of a type which has a functional group capable of self-cross-linking and which is cross-linked and solidified merely by heating without the use of a catalyst, polymerization initiator, accelerant, or other additive. The first type is not subject to any particular limitations as long as the resin is one in which a cross-linking reaction proceeds only slightly in a diluted state such as an aqueous dispersion, but the cross-linking reaction proceeds and solidification occurs even at normal temperature when the water is vaporized. A catalyst, polymerization initiator, accelerant, or other additive may be used, and functional groups capable of self-cross-linking may be used as well. In addition, the heating aimed at completing the reaction is not subject to any particular limitations. The functional groups capable of self-cross-linking are not subject to any particular limitations, and possible examples include carboxyl group pairs, epoxy group pairs, methylol group pairs, vinyl group pairs, primary amide group pairs, alkoxysilyl group pairs, methylol and alkoxymethyl groups, carbonyl and hydrazide groups, carbodiimide and carboxyl groups, and the like. The water-dispersed acrylic resin is preferably used in cases in which the wavelength-converting substance or the oxide microparticles that contain the wavelength-converting substance have affinity for water.

A resin having a vinyl acetate content (VA content) of 25% or greater is preferable as the crosslinkable ethylene vinyl acetate resin. Preferred examples include SOLAR EVA® (Mitsui Chemicals Fabro) and the like. Examples of silicone resins include commercially-available silicone resins for use in LEDs, and the like. The term “curing resin” refers to any resin that eventually forms a network structure, and an ionomer resin or other resin in which ions are used as the medium and which forms a network can also be used.

The oxide microparticles 4 are formed by dispersing the wavelength-converting substance 6 in an oxide matrix. The oxides that constitute the microparticles can be any oxides and are not subject to any particular limitations, and preferred oxides are those that contain one or more elements selected from among silicon, zirconium, yttrium, vanadium, and phosphorous. Silica (SiO₂), zirconia (ZrO₂), YVO₄, and Y₂O₃ are more preferable from the standpoint of stability, dispersibility, and cost. These may be used separately, or multiple types may be mixed together and used.

In addition, the wavelength-converting substance 6 is not subject to any particular limitations as long as it is a substance in which ultraviolet, near-infrared, or other light of a wavelength range unable to be absorbed by a photovoltaic device is converted to light of a wavelength range able to be absorbed by a photovoltaic device to generate electricity. Examples of such substances include substances containing rare-earth elements, substances containing transition metals, semiconductor microparticles, silicon nanocrystals, organic dyes, and the like. These may be used separately or in combination. Preferable rare-earth elements are europium (Eu), erbium (Er), dysprosium (Dy), and neodymium (Nd).

Examples of semiconductor microparticles include CdSe, CdTe, GaN, Si, InP, ZnO, and the like, but silicon (Si) and zinc oxide (ZnO) are preferable semiconductor microparticles for which resource exhaustion is not a concern, toxicity is comparatively low, handling is easy, and cost is low. The semiconductor microparticles preferably have a grain size of 1 to 10 nm, and more preferably 1 to 5 nm.

These wavelength-converting substances 6 may be used separately, or multiple types may be mixed together and used.

Further, the wavelength-converting substance 6 is dispersed in the oxide matrix of the oxide microparticles 4. The content of the wavelength-converting substance 6 in the oxide microparticles 4 is preferably kept higher from the standpoint of securing reliable conversion of the wavelength of incident light, but the substance will aggregate and no longer disperse uniformly when the content is too high. In view of this, the content of the wavelength-converting substance 6 in the oxide microparticles 4, as a molar fraction of the aforementioned rare-earth elements relative to all of the elements except oxygen in the oxide microparticles, is preferably 0.1 to 10 mol %, and more preferably 0.1 to 5 mol % when europium (Eu), erbium (Er), dysprosium (Dy), neodymium (Nd), and other rare-earths are used in the wavelength-converting substance, and is preferably 1 to 80 vol %, and more preferably 30 to 60 vol %, as a volume fraction of semiconductor microparticles in the oxide microparticles when such semiconductor microparticles are used.

In addition, superfine particles whose particle diameter is less than twice the Bohr radius are preferably uniformly dispersed without aggregation in the matrix to obtain microparticles in order to increase the wavelength conversion efficiency in cases such as when the wavelength-converting substance is composed of semiconductor microparticles. A mean particle diameter of 1 to 5 nm is more preferable.

Further, metallic elements may be included with an aim to modify or widen the absorption wavelength range in cases in which the oxide microparticles are YVO₄ or Y₂O₃. The included metallic elements are not subject to any limitations as long as the elements are substances that modify or widen the absorption wavelength range, and bismuth (Bi) is preferable.

Methods for producing the oxide microparticles 4 that contain the wavelength-converting substance 6 for converting the wavelength of absorbed light are not subject to any particular limitations and include, for example, the sol-gel method, polymerization of complex compounds, the PVA method, uniform precipitation of complexes, the reverse micelle method, the colloidal deposition method, the hot soap method, the supercritical hydrothermal method, the solvothermal method, spray drying, spray pyrolysis, and the like. These may be used separately or in combination. The oxide microparticles must be dispersed uniformly in a curing resin in order to ensure transparency. A production method is therefore preferred in which the solvothermal method, reverse micelle method, or other drying process is unnecessary. Caution must be taken so as not to generate secondary aggregation during drying in cases in which a production method that has a drying step among the steps is used. Large particles having a grain size of several micrometers are readily produced and secondary aggregation often occurs in cases in which microparticles are in the form of a powder, as in the spray-drying method or the spray pyrolysis method. In these cases, however, a transparent solvent dispersion is produced by pulverizing and dispersing the microparticles in a solvent using a bead mill, ultrasonic dispersion device, or the like, and the dispersion is mixed with the curing resin to allow the oxide microparticles to be uniformly dispersed.

From the standpoint of flowability and dispersibility, the content of oxide microparticles in the wavelength-converting composition is preferably 40 to 60 vol % in terms of the volume fraction of the particles after the solvent, water, and other vaporized components contained in the wavelength-converting composition have been removed and the composition cured. The formability of the wavelength-converting composition can be ensured by providing the aforementioned content of the oxide microparticles in the wavelength-converting composition. The transparency of the layer formed by the wavelength-converting composition can be maintained and a decrease in the permeability of light can be prevented because the oxide microparticles 4 are densely packed and arranged uniformly in a regular structure when the wavelength-converting composition is provided to the photovoltaic device 1. Furthermore, not only is the amount of curing resin in the wavelength-converting layer reduced, but a structure is obtained in which the curing resin is present as fine, thin particles between the oxide microparticles, making it difficult for ultraviolet light and other light harmful to the curing resin to be absorbed by the curing resin, and resulting in better durability.

The content of the oxide microparticles 4 in the wavelength-converting composition is preferably 45 to 55 vol %. The transparency of the layer formed by the wavelength-converting composition can be further increased by providing this content of the oxide microparticles 4 in the wavelength-converting composition.

In addition, from the standpoint of flowability and dispersibility, the mean particle diameter of the oxide microparticles 4 is preferably 20 to 100 nm, more preferably 40 to 100 nm, and most preferably 45 to 55 nm. The transparency of the layer formed by the wavelength-converting composition can be further increased because the oxide microparticles 4 are prevented from aggregating and are arranged uniformly in a regular structure.

A compound or a surfactant having an alkoxy group for improving the affinity between the resin and the crosslink-enhancing catalyst, cross-linking agent, wavelength-converting substance, or oxide microparticles containing the wavelength-converting substance, and for improving the dispersibility of the wavelength-converting substance or the oxide microparticles containing the wavelength-converting substance can be included in the wavelength-converting composition.

The compound having an alkoxy group is not subject to any particular limitations as long as it is a compound having an alkoxy group. Examples include tetraethoxysilane, tetramethoxysilane, and other silicon alkoxide compounds; aminosilane, epoxysilane, acryl silane, and other silicon-containing coupling agents; alkoxy-containing compounds formed of aluminum, titanium, and other non-silicon elements; and the like. A silicon-containing silane coupling agent is preferably used as a dispersant when oxide microparticles containing zinc oxide semiconductor microparticles, which constitute a wavelength-converting substance, are dispersed in the curing resin. An agent having nitrogen or an amino group is preferable as the silane coupling agent, and an azasilane, an aminosilane, or the like is also preferable. A disilane in which the alkoxy group is bifunctional, or a monosilane in which the alkoxy group is monofunctional is preferable in cases in which an aminosilane is used, and N-(2-aminoethyl)-3-aminopropylmethyldimethoxysilane is preferable from the standpoint of balance between cost and performance. Cyclic azasilane is preferable in cases in which azasilane is used, and 2,2-dimethoxy-1,6-diaza-2-silacyclooctane or N-methyl-aza-2,2,4-trimethylsilacyclopentane is preferable from the standpoint of balance between cost and performance.

### Embodiment 2

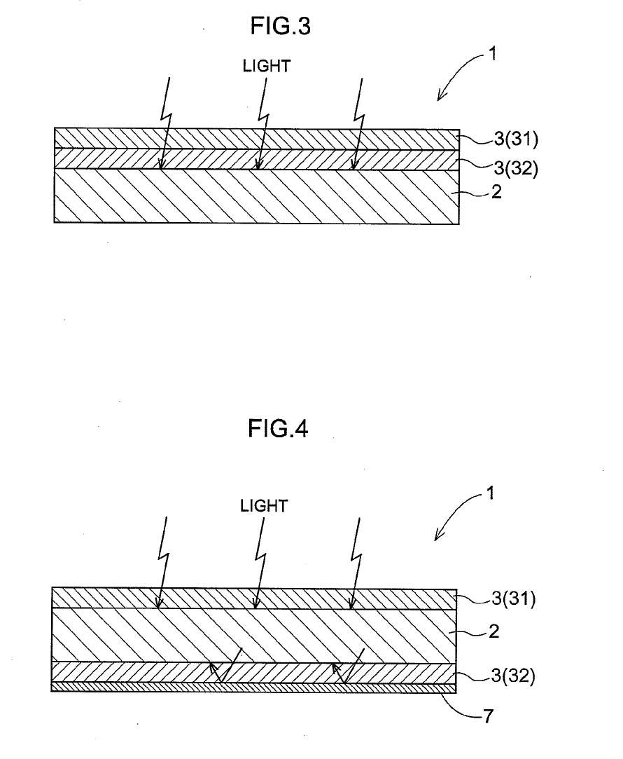

A first wavelength-converting layer 31 for converting solar rays in the ultraviolet range to the visible light range, and a second wavelength-converting layer 32 for converting solar rays in the infrared range to the visible light range may be provided as the wavelength-converting layer 3 as illustrated in FIG. 3 in the previous embodiment. In this embodiment, the layers are formed in the order of (first wavelength-converting layer 31), (second wavelength-converting layer 32) sequentially from the light-receiving side, as illustrated in the drawing. The longer the wavelength of light, the more readily the light is transmitted through the layers. Accordingly, the first wavelength-converting layer 31 for converting the short-wavelength ultraviolet range to the visible light range is provided to the light-receiving side, and the second wavelength-converting layer 32 for converting the long-wavelength infrared range to the visible light range is provided inward from the light-receiving side, whereby the wavelength conversion efficiency can be increased. The second wavelength-converting layer 32 is not limited to a layer for converting solar rays in the infrared range to the visible light range, and it is possible to use a wavelength-converting layer in which conversion to the visible light range is performed on solar rays that are in a different ultraviolet range from that of the first wavelength-converting layer 31 for converting solar rays in the ultraviolet range to the visible light range. The number of layers is not limited to two layers and may be three or more layers. Losses due to the reflection of light on the interface can be reduced, and light can be effectively supplied to the photovoltaic device by adopting an arrangement in which the refraction index of each wavelength-converting layer has a minimum value on the light-receiving side and increases in the direction of the semiconductor.

### Embodiment 3

In addition, a first wavelength-converting layer 3 for converting solar rays in the ultraviolet range to the visible light range, and a second wavelength-converting layer 3 for converting solar rays in the infrared range to the visible light range are provided as the wavelength-converting layer 3, in which case the first wavelength-converting layer 3 may be formed on the light-receiving surface side of a photovoltaic layer 2, the second wavelength-converting layer 3 may be formed on the reverse surface of the photovoltaic layer 2, and a reflective layer 7 may be provided to the side of the second wavelength-converting layer 3 that is opposite from the photovoltaic layer 2, as illustrated in FIG. 4.

### Embodiment 4

In the previous embodiment, an example is described in which the wavelength-converting composition is applied to the photovoltaic device 1 and cured to form the wavelength-converting layer 3, but this example is non-limiting. For example, the wavelength-converting layer 3 may be formed by forming a film in which the wavelength-converting composition has been cured, and providing the film to the photovoltaic device 1 using a bonding agent or the like.

### Embodiment 5

In the previous embodiment, the wavelength-converting layer 3 may be disposed so as to create a raised and depressed pattern on the surface of the photovoltaic device. Light-transmission loss, reflection loss at the interface of the photovoltaic device and the wavelength-converting layer, and the like can thereby be reduced, and light converted by the wavelength-converting layer can be efficiently supplied to the photovoltaic device. A structure having a discontinuous raised and depressed pattern in the surface is also referred to herein as a wavelength-converting layer.

From the standpoint of balance between cost and the absorption of solar light from an oblique direction, the raised and depressed pattern preferably has a height differential of 300 nm to 100 μm, more preferably 1 to 50 μm, and most preferably 10 to 50 μm. The height differential of the raised and depressed pattern can be measured using an atomic force microscope, a confocal microscope, a laser microscope, or other microscope.

In addition, the in-plane periodicity of the raised and depressed pattern is preferably 300 nm to 50 μm. The in-plane periodicity is preferably substantially the same as the light absorption wavelength range of the wavelength-converting composition. The periodicity of the raised and depressed pattern in perpendicular directions (X direction, Y direction) within a plane may be the same or different. In addition, there may be variations of the in-plane periodicity in the same direction. The in-plane periodicity of the raised and depressed pattern can be determined by performing Fourier transformation on the image information measured using an atomic force microscope, a confocal microscope, a laser microscope, a field emission scanning electron microscope (FE-SEM), or other microscope.

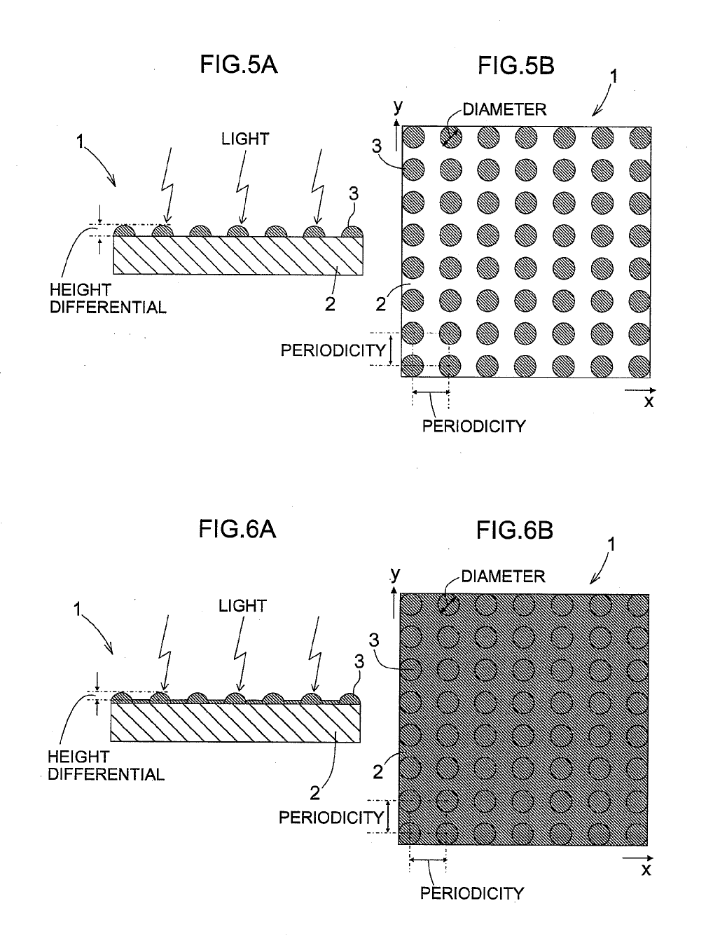

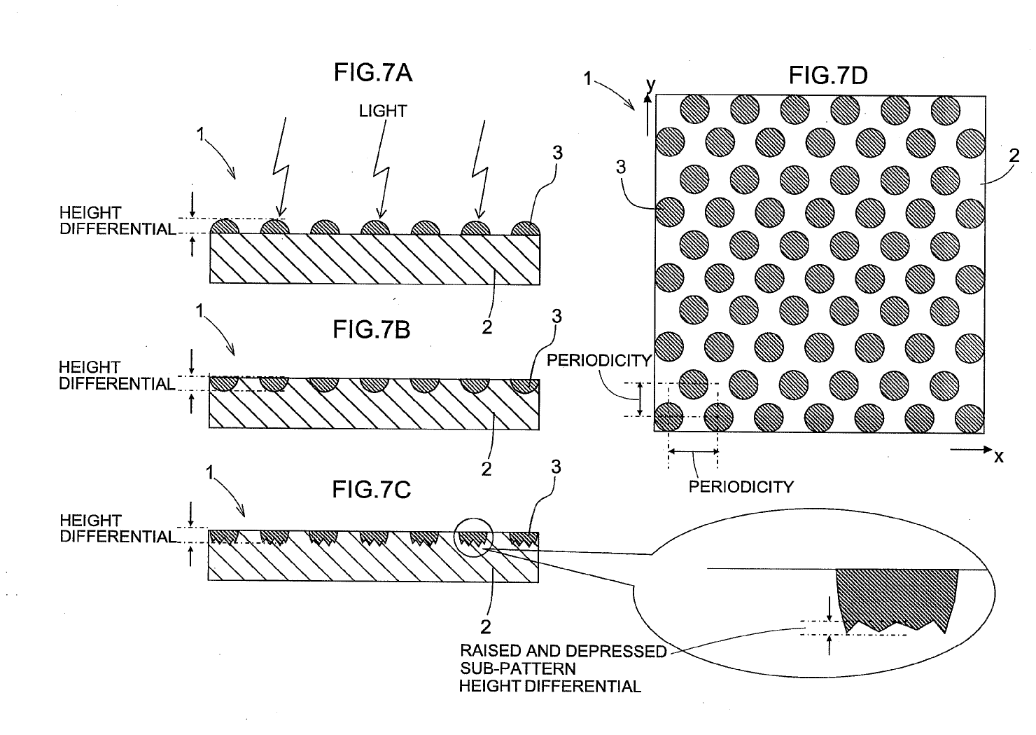

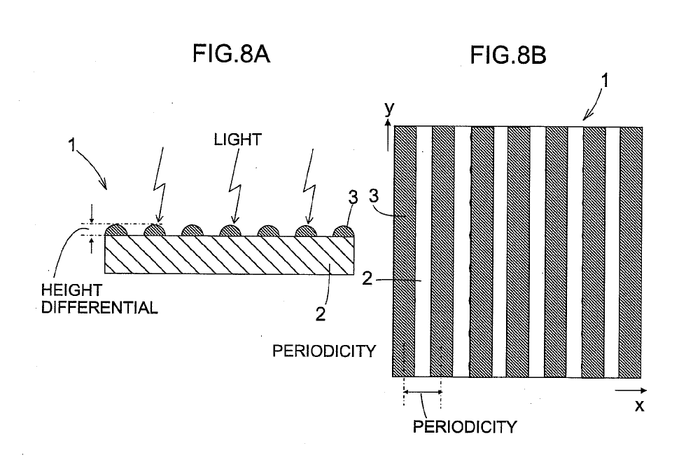

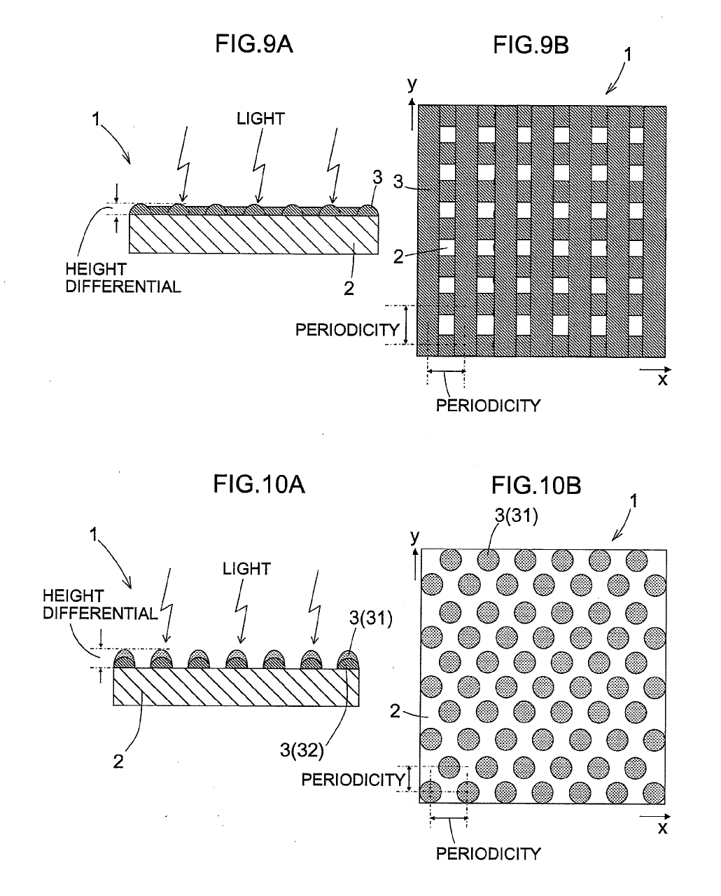

Dot, micro-lens, L&S, honeycomb, cell, square pyramid, moth-eye, conical, and other types of patterns can be employed as the raised and depressed pattern. From the standpoint of cost and efficacy, dot, micro-lens, L&S, cell, and square pyramid shapes are preferred, and dot and micro-lens shapes are more preferred. In the raised and depressed pattern, the raised side may be the side irradiated by light or the side facing the photovoltaic device. A smaller raised and depressed pattern can also be employed. The side facing the photovoltaic device is preferably raised from the standpoint of supplying a substantial amount of emitted light to the photovoltaic device. A more preferred shape is one in which the side facing the photovoltaic device is raised, and the raised pattern further has a raised and depressed sub-pattern. From the standpoint of light containment and the like, the raised and depressed sub-pattern preferably has a height differential of 100 to 500 nm. Two or more types of wavelength-converting layers may be laminated in the raised and depressed pattern. Examples of the aforementioned raised and depressed pattern are illustrated in FIGS. 5 through 10.

The raised and depressed pattern can be formed on the surface of the photovoltaic device, the surface that is opposite from the photovoltaic device, or both surfaces. In cases in which the raised and depressed pattern is formed on the surface of the side facing the photovoltaic device, a raised and depressed sub-pattern may be formed on the front surface of the photovoltaic device by using the wavelength-converting composition or another resin composition, after which a wavelength-converting composition may be applied thereon. In such cases, the in-plane periodicity of raised and depressed pattern on the surface of the side facing the photovoltaic device is preferably in the range of 300 nm to 1 μm. In cases in which a raised and depressed pattern is formed on both surfaces, that is, the surface opposite from the photovoltaic device and the surface on the side facing the photovoltaic device, the in-plane periodicity of raised and depressed pattern on the surface of the side facing the photovoltaic device is preferably smaller than the in-plane periodicity of the raised and depressed pattern on the surface opposite from the photovoltaic device.

In the raised and depressed pattern, adjacent raised and depressed areas may be composed of the same wavelength-converting composition or different wavelength-converting compositions. In cases in which the light-absorption wavelength range of the wavelength-converting composition is relatively narrow, the power-generating efficiency of the photovoltaic device can be efficiently improved by using different wavelength-converting compositions for adjacent raised and depressed areas with the aim of broadening the light-absorption wavelength range.

After the raised and depressed pattern is formed, a different resin composition can be further applied as an overcoat on the raised and depressed pattern. Soiling resistance, durability, and the like can thereby be prevented from being adversely affected.

### Embodiment 6

In the previous embodiment, spraying, dispensing, ink-jetting, or various other methods can be used to apply the wavelength-converting layer 3. When considering coating speed, device cost, microshape drawing precision, and the like, coating by ink-jetting is preferred, and piezo or electrostatic ink-jetting, which is capable of handling relatively high viscosities, is preferred among these.

The content of the present invention will now be described in detail with reference to examples. The present invention is not limited to the examples below as long as the scope thereof is not exceeded.

### Example 1

(1) Oxide Microparticles Containing Wavelength-Converting Substance

Designated quantities of zirconium tetrachloride (ZrCl₄) and europium chloride (EuCl₃.6H₂O) were dissolved in isopropyl alcohol having a water content of ≦50 ppm, and while heating under reflux, an isopropyl alcohol solution in which were dissolved designated quantities of water and N,N-dimethylaminoethyl acrylate was added slowly using a metering pump. Following a reflux process of sufficient duration, additional zirconium tetrachloride (ZrCl₄) was dissolved, an isopropyl alcohol solution in which were dissolved designated quantities of water and N,N-dimethylaminoethyl acrylate was added slowly using a metering pump, and additional reflux was carried out for a sufficient duration. The respective added amounts of zirconium tetrachloride (ZrCl₄) and europium chloride (EuCl₃.6H₂O) were adjusted to give a Zr to Eu concentration ratio (molar ratio) of 100:1. Then, using an ultrafiltration membrane or the like, unreacted material and byproducts were removed, and concentration was performed if necessary, to obtain an oxide in the form of an isopropyl alcohol dispersion having an oxide weight fraction of 20 wt %. A fluorescent X-ray unit (RIX2000 by Rigaku) showed that Zr:Eu=100:1. The isopropyl alcohol dispersed oxide was dried, and the oxide weight fraction was confirmed to be 20 wt % from the residual weight subsequent to heating for 1 hour at 400° C. The absolute specific gravity was 5.8. Small angle X-ray scattering measurements revealed the oxide microparticles to have a mean particle diameter of 52 nm at a standard deviation of 10 nm, while FE-SEM examination revealed that the oxide microparticles were substantially spherical.

(2) Wavelength-Converting Composition

Norbornane dimethylol diacrylate (trial product number: TO-2111 by To a Gosei) having the structure of General Formula (2), where X, R³, and R⁴ are each a hydrogen, and p is 0; γ-acryloxypropyl methyl dimethoxysilane; and the isopropyl alcohol dispersed oxide prepared in (1) (oxide content: 20 wt %, mean particle diameter: 50 nm, standard deviation: 10 nm) were combined in proportions such that the cured wavelength-converting composition would have an oxide volume fraction of 50 vol %, and the volatile fraction was removed under a vacuum while stirring at 45° C. Thereafter, the photopolymerization initiator 1-hydroxycyclohexyl phenyl ketone (Irgacure 184 by Ciba Specialty Chemicals) was dissolved, and the volatile fraction was further removed under a vacuum to obtain the wavelength-converting composition. The solvent content of the wavelength-converting composition was less than 10%.

The wavelength-converting composition was found to have flowability both at normal temperature and when heated. The wavelength-converting composition was cured and annealed together with a resin composition prepared by the same method as above except for the absence of the added transparent dispersed solution of compound oxide microparticles prepared in (1); the specific gravity of the cured articles was measured; and the oxide microparticle weight fraction was confirmed to be the one specified previously from the residual weight of the cured and annealed wavelength-converting composition that had also been heated for 1 hour at 400° C.

(3) Evaluations

(3-1) Transparency and Linear Expansion Coefficient

The resulting wavelength-converting composition was heated in an oven at a designated temperature (60 to 80° C.), injected into a frame having a thickness of 0.15 mm on a glass plate, and covered from above with a glass plate to fill the frame interior with the wavelength-converting composition. The wavelength-converting composition sandwiched between glass plates obtained in (2) was cured by irradiation with ultraviolet light from both sides at about 500 mJ/cm², and the sheet was peeled off from the glass. The resulting sheet was heated in a vacuum oven for 3 hours at about 100° C., and then for 3 hours at about 275° C. to obtain a sample in the form of a sheet. The thickness of the sheet sample was measured with a micrometer and found to be 140 μm.

Using a TMA/SS120C thermomechanical analyzer made by Seiko Instruments, the sheet sample was kept for 20 minutes under nitrogen while the temperature was raised from 30° C. to 400° C. at a rate of 5° C. per minute, and the relevant values were measured at a temperature of from 30 to 230° C. The results of measurements taken at a load of 5 g in tensile mode showed the average linear coefficient of expansion to be 41 ppm/° C.

The haze of the sheet sample was measured using an NDH2000 made by Nippon Denshoku Industries, and was found to be 0.5; and the collimated beam transmittance was measured using a U3200 (Hitachi Ltd.) and a UV-24002C (Shimadzu) spectrophotometer, and was found to be 92%. Examination with the naked eye also revealed the sample to be an extremely transparent sheet.

(3-2) Power Generating Efficiency

The composite resin composition and resin composition obtained in (2) were applied in a thickness of about 1 μm to the surface of a commercially available amorphous silicon solar cell to produce the final solar cell. Measurement of power generating efficiency of this cell showed that power generating efficiency could be improved by about 2%.

### Example 2

(1) Oxide Microparticles Containing Wavelength-Converting Substance

Designated quantities of yttrium nitrate hexahydrate, bismuth nitrate, europium nitrate hexahydrate, and sodium orthovanadate were dissolved in isopropyl alcohol having a water content of ppm, and while heating under reflux, an isopropyl alcohol solution in which were dissolved designated quantities of water and N,N-dimethylaminoethyl acrylate was added slowly using a metering pump. Following a reflux process of sufficient duration, additional yttrium nitrate hexahydrate and sodium orthovanadate were dissolved, an isopropyl alcohol solution in which were dissolved designated quantities of water and N,N-dimethylaminoethyl acrylate was added slowly using a metering pump, and additional reflux was carried out for a sufficient duration. Then, using an ultrafiltration membrane or the like, unreacted material and byproducts were removed, and concentration was performed if necessary, to obtain an oxide in the form of an isopropyl alcohol dispersion having an oxide concentration of 20 wt %. The absolute specific gravity was 4.3. The composition of the oxide was YVO₄:Bi³⁺, Eu³⁺. The proportions were such that the Bi³⁺ content and the Eu³⁺ content in the YVO₄, expressed as Bi/(Y+V+O+Bi+Eu), Eu/(Y+V+O+Bi+Eu)m, respectively, were each 0.5 mol %. A fluorescent X-ray unit (RIX2000 by Rigaku) showed that Y:V:Bi:Eu=94:98:3:3. The isopropyl alcohol dispersed oxide was dried, and the oxide weight fraction was confirmed to be 20 wt % from the residual weight subsequent to heating for 1 hour at 400° C. Small angle X-ray scattering measurements revealed the oxide microparticles to have a mean particle diameter of 45 nm at standard deviation of 9 nm, while FE-SEM examination revealed that the oxide microparticles were substantially spherical.

(2) Wavelength-Converting Composition

Norbornane dimethylol diacrylate (trial product number: TO-2111 by To a Gosei) having the structure of General Formula (2), where X, R³, and R⁴ are each a hydrogen, and p is 0; γ-acryloxypropyl methyl dimethoxysilane; and the isopropyl alcohol dispersed oxide prepared in (1) (oxide content: 20 wt %, mean particle diameter: 50 nm, standard deviation: 10 nm) were combined in proportions such that the cured wavelength-converting composition would have an oxide volume fraction of 50 vol %, and the volatile fraction was removed under a vacuum while stirring at 45° C. Thereafter, the photopolymerization initiator 1-hydroxycyclohexyl phenyl ketone (Irgacure 184 by Ciba Specialty Chemicals) was dissolved, and the volatile fraction was further removed under a vacuum to obtain the wavelength-converting composition. The solvent content of the wavelength-converting composition was less than 10%.

The wavelength-converting composition was found to have flowability both at normal temperature and when heated. The wavelength-converting composition was cured and annealed together with a resin composition prepared by the same method as above except for the absence of the added transparent dispersed solution of compound oxide microparticles prepared in (1); the specific gravity of the cured articles was measured; and, based on the residual weight of the cured and annealed wavelength-converting composition that had also been heated for 1 hour at 400° C., the oxide microparticle weight fraction was confirmed to be the one specified previously.

(3) Evaluations

(3-1) Transparency and Linear Expansion Coefficient

The resulting wavelength-converting composition was heated in an oven at a designated temperature (60 to 80° C.), injected into a frame having a thickness of 0.15 mm on a glass plate, and covered from above with a glass plate to fill the frame interior with the wavelength-converting composition. The wavelength-converting composition sandwiched between glass plates obtained in (2) was cured by irradiation with ultraviolet light from both sides at about 500 mJ/cm², and the sheet was peeled off from the glass. The resulting sheet was heated in a vacuum oven for 3 hours at about 100° C., and then for 3 hours at about 275° C. to obtain a sample in the form of a sheet. The thickness of the sheet sample was measured with a micrometer and found to be 140 μm.

Using a TMA/SS120C thermomechanical analyzer made by Seiko Instruments, the sheet sample was kept for 20 minutes under nitrogen while the temperature was raised from 30° C. to 400° C. at a rate of 5° C. per minute, and the relevant values were measured at a temperature of from 30 to 230° C. The results of measurements taken at a load of 5 g in tensile mode showed the average linear coefficient of expansion to be 42 ppm/° C.

The haze of the sheet sample was measured using an NDH2000 made by Nippon Denshoku Industries, and was found to be 0.6; and the collimated beam transmittance was measured using a UV-2400PC (Shimadzu) spectrophotometer and was found to be 91%. Examination with the naked eye also revealed the sample to be an extremely transparent sheet.

(3-2) Power Generating Efficiency The composite resin composition and resin composition obtained in (2) were applied in a thickness of about 1 μm to the surface of a commercially available crystalline silicon solar cell to produce the final solar cell. Measurement of power generating efficiency of this cell showed that power generating efficiency was improved by about 3%.

### Example 3

(1) Oxide Microparticles Containing Wavelength-Converting Substance

Oxide microparticles containing a wavelength-converting substance were prepared in the same manner as in Example 1, except for replacing the europium nitrate hexahydrate with neodymium nitrate hexahydrate. The composition of the oxide was YVO₄:Bi³⁺, Nd³⁺. The absolute specific gravity was 4.3. The proportions were such that the Bi³⁺ content and the Nd³⁺ content in the YVO₄, expressed as Bi/(Y+V+O+Bi+Nd), Nd/(Y+V+O+Bi+Nd), respectively, were each 0.5 mol %. A fluorescent X-ray unit (RIX2000 by Rigaku) showed that Y:V:Bi:Nd=94:95:3:3. The isopropyl alcohol dispersed oxide was dried, and the oxide weight fraction was confirmed to be 20 wt % from the residual weight subsequent to heating for 1 hour at 400° C. Small angle X-ray scattering measurements revealed the oxide microparticles to have a mean particle diameter of 51 nm at a standard deviation of 10 nm, while FE-SEM examination revealed that the oxide microparticles were substantially spherical.

(2) Wavelength-Converting Composition

A wavelength-converting composition was obtained in the same manner as in Example 2, except that the oxide microparticles containing the wavelength-converting substance consisted of YVO₄:Bi³⁺, Nd³⁺, and was evaluated in the same manner. The solvent content of the wavelength-converting composition was less than 10%.

The wavelength-converting composition was found to have flowability both at normal temperature and when heated. The wavelength-converting composition was cured and annealed together with a resin composition prepared by the same method as above except for the absence of the added transparent dispersed solution of compound oxide microparticles prepared in (1); the specific gravity of the cured articles was measured; and, based on the residual weight of the cured and annealed wavelength-converting composition that had also been heated for 1 hour at 400° C., the oxide microparticle weight fraction was confirmed to be the one specified previously.

(3) Evaluations

The thickness of the sheet sample was measured with a micrometer and found to be 141 μm. The average linear coefficient of expansion of the resulting wavelength-converting composition was found to be 42 ppm/° C. Haze measurement gave a result of 0.9, and the collimated beam transmittance was 91%. Measurement of power generating efficiency showed that in a crystalline silicon solar cell, power generating efficiency was improved by about 3%.

### Example 4

The wavelength-converting composition obtained in Example 1 was applied onto the surface of a commercially available amorphous silicon solar cell, using a piezoelectric inkjet to produce a final solar cell having a microlens pattern such as that depicted in FIG. 5. Microscope examination revealed that the microlens pattern diameter, height differential of the raised and depressed structures, and periodicity were about 30 μm, about 10 μm, and about 40 μm, respectively. The power generating efficiency was measured and found to have improved by about 3%.

### Example 5

The wavelength-converting composition obtained in Example 2 was applied onto the surface of a commercially available crystalline silicon solar cell, using a piezoelectric inkjet to produce a final solar cell having a microlens pattern such as that depicted in FIG. 5. Microscope examination revealed that the microlens pattern diameter, height differential of the raised and depressed structures, and periodicity were about 30 μm, about 10 μm, and about 40 μm, respectively. The power generating efficiency was measured and found to have improved by about 4%.

### Example 6

The wavelength-converting composition obtained in Example 3 was applied onto the surface of a commercially available crystalline silicon solar cell, using a piezoelectric inkjet to produce a final solar cell having a microlens pattern such as that depicted in FIG. 5. Microscope examination revealed that the microlens pattern diameter, height differential of the raised and depressed structures, and periodicity were about 30 μm, about 10 μm, and about 40 μm, respectively. The power generating efficiency was measured and found to have improved by about 4%.

### Example 7

(Wavelength-Converting Silicon Microparticles)

Following the method described in Patent Document 4, an SiOₓ film was deposited onto a substrate with a high frequency sputtering unit, using a target material of silicon and quartz (surface area ratio: silicon/quartz=10/90). The film was then heat treated under argon gas. The film was affixed to a resin plate and processed for 2 minutes in 20% hydrofluoric acid aqueous solution. The silicon nanoparticles which appeared were rinsed with water. This was done until the hydrofluoric acid had been removed. The material was subjected to an ultrasonic treatment in isopropyl alcohol to give a silicon microparticle dispersion.

Using a transmission electron microscope (TEM), it was found that the silicon microparticles had a mean particle diameter of 3 nm at a standard deviation of 1 nm, and that the silicon microparticles were substantially spherical. The absolute specific gravity was 2.3. Based on the residual weight subsequent to heating the dispersion for 1 hour at 400° C., it was found that the weight ratio of compound oxide microparticles to isopropyl alcohol in the dispersion was 1:99.

(2) Wavelength-Converting Composition

Norbornane dimethylol diacrylate (trial product number: TO-2111 by To a Gosei) having the structure of General Formula (2), where X, R³, and R⁴ are each a hydrogen, and p is 0; γ-acryloxypropyl methyl dimethoxysilane; and the isopropyl alcohol dispersed silicon microparticles prepared in (1) (silicon microparticle content 1 wt %, mean particle diameter: 3 nm, standard deviation: 1 nm) were combined in proportions such that the cured wavelength-converting composition would have a silicon microparticle volume fraction of 5 vol %, and the volatile fraction was removed under a vacuum while stirring at 45° C. Thereafter, the photopolymerization initiator 1-hydroxycyclohexyl phenyl ketone (Irgacure 184 by Ciba Specialty Chemicals) was dissolved, and the volatile fraction was further removed under a vacuum to obtain the wavelength-converting composition. The solvent content of the wavelength-converting composition was less than 10%.

The wavelength-converting composition was found to have flowability both at normal temperature and when heated. The wavelength-converting composition was cured and annealed together with a resin composition prepared by the same method as above except that there was no addition of the dispersed solution of microparticles prepared in (1); the specific gravity of the cured articles was measured; and, based on the residual weight of the cured and annealed wavelength-converting composition that had also been heated for 1 hour at 400° C., the silicon microparticle weight fraction was confirmed to be the one specified previously.

(3) Evaluations

(3-1) Transparency and Linear Expansion Coefficient

The resulting wavelength-converting composition was heated in an oven at a designated temperature (60 to 80° C.), injected into a frame having a thickness of 0.15 mm on a glass plate, and covered from above with a glass plate to fill the frame interior with the wavelength-converting composition. The wavelength-converting composition sandwiched between glass plates obtained in (2) was cured by irradiation with ultraviolet light from both sides at about 500 mJ/cm², and the sheet was peeled off from the glass. The resulting sheet was heated in a vacuum oven for 3 hours at about 100° C., and then for 3 hours at about 275° C. to obtain a sample in the form of a sheet. The thickness of the sheet sample was measured with a micrometer and found to be 141 μm.

Using a TMA/SS120C thermomechanical analyzer made by Seiko Instruments, the sheet sample was kept for 20 minutes under nitrogen while the temperature was raised from 30° C. to 400° C. at a rate of 5° C. per minute, and the relevant values were measured at a temperature of from 30 to 230° C. The results of measurements taken at a load of 5 g in tensile mode showed the average linear coefficient of expansion to be 87 ppm/° C.

The haze of the sheet sample was measured using an NDH2000 made by Nippon Denshoku Industries, and was found to be 0.6; and the collimated beam transmittance was measured using a UV-2400PC (Shimadzu) spectrophotometer and was found to be 93%. Examination with the naked eye also revealed the sample to be an extremely transparent sheet.

(3-2) Power Generating Efficiency

The wavelength-converting composition obtained in (2) was applied in a thickness of about 1 μm to the surface of a commercially available crystalline silicon solar cell to produce the final solar cell. Microscopic examination revealed that the microlens pattern diameter, height differential of the raised and depressed structures, and periodicity were about 30 μm, about 10 μm, and about 40 μm, respectively. The power generating efficiency was measured and found to have improved by about 3%.

The above evaluations were conducted again after the photovoltaic device was allowed to stand outdoors for one month; the short-circuit current density Jsc and the conversion efficiency were observed to have decreased.

### Example 8

(Fabrication Example 1 of Oxide Microparticles Containing Wavelength-Converting Substance)

After adding tetramethoxysilane to water and mixing, the silicon microparticles prepared in Example 1 were added and stirred in. Using this dispersion and following the method described in Patent Document 6, the solution was sprayed from an ultrasonic atomizer with air as the carrier gas, and was introduced into an electric furnace to carry out a spray pyrolysis process. This yielded oxide microparticles containing 1 vol % of silicon microparticles. Isopropyl alcohol was added, and an ultrasonic treatment was carried out to produce a dispersion. Small angle X-ray scattering measurements revealed the oxide microparticles to have a mean particle diameter of 51 nm at a standard deviation of 9 nm, while FE-SEM examination revealed that the oxide microparticles were substantially spherical. The absolute specific gravity was 2.1. Based on the residual weight subsequent to heating the dispersion for 1 hour at 400° C., the weight ratio of compound oxide microparticles to isopropyl alcohol in the dispersion was found to be 20:80.

A wavelength-converting composition was prepared by the same method as in Example 7, except for replacing the silicon microparticles with the silicon-containing oxide microparticles prepared in Fabrication Example 1, and using isopropyl alcohol dispersed oxide microparticles (oxide microparticle content 20 wt %, mean particle diameter: 51 nm, standard deviation 9 nm) in a proportion such that the cured wavelength-converting composition would have an oxide microparticle volume fraction of 50 vol %. The composition was evaluated in the same manner. The solvent content of the wavelength-converting composition was less than 10%. The thickness of the sheet sample was measured with a micrometer and found to be 144 μm. The wavelength-converting composition was found to have flowability both at normal temperature and when heated. The wavelength-converting composition was cured and annealed together with a resin composition prepared by the same method as above except that there was no addition of the dispersed solution of microparticles prepared in Fabrication Example 1; the specific gravity of the cured articles was measured; and, based on the residual weight of the cured and annealed wavelength-converting composition that had also been heated for 1 hour at 400° C., the oxide microparticle weight fraction was confirmed to be the one specified previously.

The average linear coefficient of expansion of the resulting wavelength-converting composition was found to be 42 ppm/° C. Haze measurement gave a result of 0.7, and the collimated beam transmittance was 92%. Microscopic examination revealed that the microlens pattern diameter, height differential of the raised and depressed structures, and periodicity were about 30 μm, about 10 μm, and about 40 μm, respectively. The power generating efficiency of the crystalline silicon solar cell was measured and found to have improved by about 3%.

### Example 9

(Fabrication Example 2 of Oxide Microparticles Containing Wavelength-Converting Substance)

The silicon microparticles prepared in Example 1 (volume fraction: colloidal silica/silicon microparticles=99/1) were added to and stirred with colloidal silica (dispersion medium: isopropyl alcohol) having a mean particle diameter of 5 nm. Using this dispersion and following the procedure described in Non-patent Document 2, the solution was sprayed from an ultrasonic atomizer with nitrogen as the carrier gas, and was introduced into an electric furnace to carry out a spray drying process. This yielded oxide microparticles containing 1 vol % of silicon microparticles. Isopropyl alcohol was added, and an ultrasonic treatment was carried out to produce a dispersion. Small angle X-ray scattering measurements revealed the oxide microparticles to have a mean particle diameter of 50 nm at a standard deviation of 8 nm, while FE-SEM examination revealed that the oxide microparticles were substantially spherical. The absolute specific gravity was 2.1. Based on the residual weight subsequent to heating the dispersion for 1 hour at 400° C., the weight ratio of compound oxide microparticles to isopropyl alcohol in the transparent dispersion was found to be 20:80.

A wavelength-converting composition was prepared by the same method as in Example 7, except for replacing the silicon microparticles with the silicon-containing oxide microparticles prepared in Fabrication Example 2, and using isopropyl alcohol dispersed oxide microparticles (oxide microparticle content 20 wt %, mean particle diameter: 50 nm, standard deviation 8 nm) in a proportion such that the cured wavelength-converting composition would have an oxide microparticle volume fraction of 50 vol %. The composition was evaluated in the same manner. The solvent content of the wavelength-converting composition was less than 10%. The thickness of the sheet sample was measured with a micrometer and found to be 142 μm.

The wavelength-converting composition was found to have flowability both at normal temperature and when heated. The wavelength-converting composition was cured and annealed together with a resin composition prepared by the same method as above except that there was no addition of the dispersed solution of microparticles prepared in Fabrication Example 2; the specific gravity of the cured articles was measured; and, based on the residual weight of the cured and annealed wavelength-converting composition that had also been heated for 1 hour at 400° C., the oxide microparticle weight fraction was confirmed to be the one specified previously.

The average linear coefficient of expansion of the resulting wavelength-converting composition was found to be 43 ppm/° C. Haze measurement gave a result of 0.8, and the collimated beam transmittance was 91%. Microscopic examination revealed that the microlens pattern diameter, height differential of the raised and depressed structures, and periodicity were about 30 μm, about 10 μm, and about 40 μm, respectively. The power generating efficiency of the crystalline silicon solar cell was measured and found to have improved by about 3%.

### Example 10

(Fabrication Example 3 of Oxide Microparticles Containing Wavelength-Converting Substance)

The silicon microparticles prepared in Example 1 (volume fraction: colloidal silica/silicon microparticles=99/1) were added to and stirred with colloidal silica (dispersion medium: isopropyl alcohol) having a mean particle diameter of 5 nm. Using this dispersion and following the procedure described in Non-patent Document 2, the solution was sprayed from an ultrasonic atomizer with nitrogen as the carrier gas, and was introduced into an electric furnace to carry out a spray drying process. This yielded oxide microparticles containing 1 vol % of silicon microparticles. Water was added, and an ultrasonic treatment was carried out to produce a dispersion. Small angle X-ray scattering measurements revealed the oxide microparticles to have a mean particle diameter of 50 nm at a standard deviation of 8 nm, while FE-SEM examination revealed that the oxide microparticles were substantially spherical. The absolute specific gravity was 2.1. Based on the residual weight subsequent to heating the dispersion for 1 hour at 400° C., the weight ratio of compound oxide microparticles to water in the transparent dispersion was found to be 20:80.

The water-dispersed, silicon-containing oxide microparticles (oxide microparticle content 20 wt %, mean particle diameter: 50 nm, standard deviation 8 nm) prepared in Fabrication Example 3 were combined with a self-crosslinking acrylic resin (a water-based emulsion containing a combination of diacetone acrylamide and adipic acid dihydrazide) in a proportion such that the cured wavelength-converting composition would have an oxide microparticle volume fraction of 50 vol % with respect to the resin; and the excess water was removed to obtain the wavelength-converting composition, which was then evaluated in the same manner as in Example 7. The thickness of the sheet sample was measured with a micrometer and found to be 141 μm.

The wavelength-converting composition was found to have flowability both at normal temperature and when heated. The wavelength-converting composition was cured and annealed together with a resin composition prepared by the same method as above except that there was no addition of the dispersed solution of microparticles prepared in Fabrication Example 3; the specific gravity of the cured articles was measured; and, based on the residual weight of the cured and annealed wavelength-converting composition that had also been heated for 1 hour at 400° C., the oxide microparticle weight fraction was confirmed to be the one specified previously.

The average linear coefficient of expansion of the resulting wavelength-converting composition was found to be 41 ppm/° C. Haze measurement gave a result of 0.7, and the collimated beam transmittance was 92%. Microscope examination revealed that the microlens pattern diameter, height differential of the raised and depressed structures, and periodicity were about 30 μm, about 10 μm, and about 40 μm, respectively. The power generating efficiency of the crystalline silicon solar cell was measured and found to have improved by about 2%.

### Example 11

(1) Oxide Microparticles Containing Wavelength-Converting Substance

To 40 mL of water were added 1.00 g of yttrium nitrate hexahydrate, 0.09 g of europium nitrate hexahydrate, and 21 mL of 0.1 M sodium citrate aqueous solution. To this was added 0.48 g of bismuth citrate, followed by dispersion for 1 minute with ultrasound to obtain Solution 1. Meanwhile, 0.55 g of sodium orthovanadate was added to 40 mL whose pH had been adjusted to 12.5, and the resulting solution was designated Solution 2.

Solution 2 was added to Solution 1 under stirring at 60 to 70° C., and aged for 4 hours at 60 to 70° C. The solution was cooled to room temperature. Impurities were removed from the resulting solution by centrifugal separation, membrane separation, or the like. The dispersion was then concentrated. Based on the residual weight of the dispersion after heating for 1 hour at 400° C., the weight ratio of oxide microparticles to water in the dispersion was found to be 1:99. As a result of measuring the dispersion using a dynamic light scattering unit (Zetasizer Nano ZS made by Malvern Instruments), the oxide microparticles were found to have a Z mean particle diameter of 46 nm. The particle diameter distribution was relatively sharp as well. Small angle X-ray scattering measurements revealed the oxide microparticles to have a mean particle diameter of 45 nm. Further, using a fluorescence spectrophotometer (F-2500 made by Hitachi High Technologies), the PL spectrum of the dispersion was measured. As a result, it was found that the maximum luminescence peak with excitation at 360 nm was 600 nm or greater. Additionally, the quantum yield and absorptance of the dispersion were measured using an absolute PL quantum yield measurement system (C9920-02G made by Hamamatsu Photonics). As a result, it was found that the quantum yield with excitation at 360 nm was 40% or greater, and the absorptance was 90% or greater. The absolute specific gravity of the particles was 4.7.

(2) Wavelength-Converting Composition

The water-dispersed oxide microparticles prepared in (1) were combined with a self-crosslinking acrylic resin (a water-based emulsion containing a combination of diacetone acrylamide and adipic acid dihydrazide) in a proportion such that the cured wavelength-converting composition would have an oxide microparticle volume fraction of 50 vol % with respect to the resin; and the excess water was removed to obtain the wavelength-converting composition. The wavelength-converting composition was found to have flowability both at normal temperature and when heated. The wavelength-converting composition was cured and annealed together with a resin composition prepared by the same method as above except that there was no addition of the dispersed solution of oxide microparticles prepared in (1), the specific gravity of the cured articles was measured, and the residual weight of the cured and annealed wavelength-converting composition that had also been heated for 1 hour at 400° C. was measured. Based on this result, the oxide microparticle weight fraction was calculated and found to be 48 vol %.

(3) Evaluations

(3-1) Transparency and Linear Expansion Coefficient

The wavelength-converting composition obtained in (2) was applied within a frame having a thickness of 0.35 mm on a glass plate, and dried to produce a sample in the form of a sheet. The thickness of the sheet sample was measured with a micrometer and found to be 142 μm.

Using a thermomechanical analyzer (TMA/SS120C made by Seiko Instruments), the sheet sample was kept for 20 minutes under nitrogen while the temperature was raised from 30° C. to 400° C. at a rate of 5° C. per minute, and the relevant values were measured at a temperature of from 30 to 230° C. The results of measurements taken at a load of 5 g in tensile mode showed the average linear coefficient of expansion to be 43 ppm/° C.

The haze of the sheet sample was measured using a haze meter (NDH2000 made by Nippon Denshoku Industries), and was found to be 0.5; and the collimated beam transmittance was measured using a spectrophotometer (UV-2400PC made by Shimadzu) and was found to be 92%. Examination with the naked eye also revealed the sample to be an extremely transparent sheet.

(3-2) Power Generating Efficiency

Using a spin coater, the wavelength-converting composition prepared in (2) was applied in a dry thickness of about 20 μm to the smooth face of cover glass for a crystalline silicon solar cell. An EVA (VA content 28%; crosslinking type) sealant sheet for solar cell applications was laid over a commercially available monocrystalline silicon solar cell, and the cover glass was further placed thereon, with the coated face facing downward. The assembly was subjected to a vacuum heat treatment to fabricate a photovoltaic device.

The measurements performed to determine the short-circuit current density Jsc (mA/cm²) and conversion efficiency of the aforementioned photovoltaic device will now be described. Using a simulated sunlight irradiation system (Model OTENTO-SUN V Solar Simulator made by Bunkoukeiki), the device was irradiated with light at 1 kW/m², and the current and voltage produced at that time were measured in accordance with JIS C 8913, using an I-V tester (Model 2400 SourceMeter made by Keithly Instruments). A value derived by subtracting the short-circuit current density Jsc of a photovoltaic device, which was prepared by the exactly the same method as above but without including the wavelength-converting layer 3, from the measured short-circuit current density Jsc was designated as the short-circuit current density differential ΔJsc. As a result, ΔJsc was found to be 0.50 mA/cm², and the conversion efficiency had improved by 1.7% over the conversion efficiency of the photovoltaic device lacking the wavelength-converting layer 3. Five of each of the above photovoltaic devices were fabricated, and the average values for these were adopted for the short-circuit current density and conversion efficiency.

The above evaluations were carried out after the photovoltaic device was allowed to stand outdoors for one month, and no decline in Jsc or conversion efficiency was observed.

The wavelength-converting composition prepared in (2) was applied in a microlens pattern onto the surface of the smooth face of cover glass for a crystalline silicon solar cell using a commercially available inkjet (electrostatic). Examination with a laser microscope (VK-9700 made by Keyence) revealed that the microlens pattern diameter, height differential of the raised and depressed structures, x-axis direction periodicity, and y-axis direction periodicity were about 30 μm, about 20 μm, about 35 μm, and about 30 μm, respectively. The short-circuit current density differential and conversion efficiency of photovoltaic devices fabricated by the above method were measured, and it was found that ΔJsc was 0.88 mA/cm² and that the conversion efficiency had improved by 2.9%.

The above evaluations were carried out after the photovoltaic device was allowed to stand outdoors for one month, and no decline in Jsc or conversion efficiency was observed.

### Example 12

(1) Oxide Microparticles Containing Wavelength-Converting Substance

1) Preparation of Wavelength-Converting Substance (Zinc Oxide Semiconductor Microparticles)

200 mL of an ethanol solution of zinc oxide dihydrate prepared to a zinc oxide dihydrate concentration of 0.1 M was stirred and heated for about 3 hours at about 80° C. while condensing the total quantity of solution to 80 mL. Next, the aforementioned 80 mL of condensed solution and 120 mL of an ethanol solution of lithium hydroxide monohydrate prepared to a lithium hydroxide monohydrate concentration of 0.23 M were mixed at a temperature of 10° C. or less, and filtered through a filter having a pore size of 0.2 μm, and the impurities were removed by membrane separation or the like to obtain a transparent mixed solution. This mixed solution exhibited bright luminescence with exposure to ultraviolet light, showing that zinc oxide semiconductor microparticles had formed in the mixed solution.

2) Preparation of Oxide Microparticles That Contain Zinc Oxide Semiconductor Microparticles

An organosilica sol made by Nissan Chemical (product number: IPA-ST, mean particle diameter of silica particles: about 12 nm, silica particle concentration: 30 wt %, solvent: 2-propanol) was diluted 35-fold with ethanol to prepare a mixed solution having a silica particle concentration of 0.26 M. Next, a 10 mL portion of this mixed solution was combined with a 40 mL portion of the mixed solution prepared in (1), and compound oxide microparticles that contained zinc oxide semiconductor microparticles and silica particles were produced by a spray drying process. The above procedure was carried out repeatedly to produce a designated quantity of compound oxide microparticles. During the spray drying process, the furnace temperature was 450° C. and the carrier gas was nitrogen. The resulting compound oxide microparticles had an absolute specific gravity of 4.0, and the approximate volume ratio of zinc oxide semiconductor microparticles and silica particles in the compound oxide microparticles was as follows: zinc oxide semiconductor microparticles/silica particles=6:5.

3) Preparation of Oxide Microparticle Dispersed Solution

2.1 g of the compound oxide microparticles prepared as above were combined with 47.9 g of ethanol, and after dispersion using an ultrasonic dispersion unit, the impurities were removed by centrifugal separation, membrane separation, or the like to obtain a transparent dispersion containing dispersed compound oxide microparticles. Based on the residual weight of the transparent dispersion after heating for 1 hour at 400° C., the weight ratio of compound oxide microparticles to ethanol in the transparent dispersion was found to be 1:24. As a result of measuring the transparent dispersion using a dynamic light scattering unit (Zetasizer Nano ZS made by Malvern Instruments), the compound oxide microparticles were found to have a Z mean particle diameter of 52 nm. The particle diameter distribution was relatively sharp as well. Small angle X-ray scattering measurements revealed the compound oxide microparticles to have a mean particle diameter of 50 nm. Further, the PL spectrum of the transparent dispersion was measured using a fluorescence spectrophotometer (F-2500 made by Hitachi High Technologies). As a result, it was found that the luminescence peak wavelength with excitation at 360 nm was 500 nm or greater. Additionally, the quantum yield and absorptance of the transparent dispersion were measured using an absolute PL quantum yield measurement system (C9920-02G made by Hamamatsu Photonics). As a result, it was found that the quantum yield with excitation at 360 nm was 50% or greater, and the absorptance was 90% or greater.

(2) Wavelength-Converting Composition

Norbornane dimethylol diacrylate [trial product number: TO-2111 by To a Gosei] having the structure of General Formula (2), where X, R³, and R⁴ are each a hydrogen, and p is 0; N-(2-aminoethyl)-3-aminopropyl methyl dimethoxysilane (Sila-Ace 310 made by Chisso); and the transparent dispersed solution of compound oxide microparticles prepared in (1) were combined in proportions such that the cured wavelength-converting composition would have an oxide volume fraction of 50 vol %, and the volatile fraction was removed under a vacuum while stirring at a temperature ranging from room temperature to 40° C. The weight ratio of norbornane dimethylol diacrylate to N-(2-aminoethyl)-3-aminopropyl methyl dimethoxysilane was 4:1. Thereafter, the photopolymerization initiator 1-hydroxycyclohexyl phenyl ketone (Irgacure 184 by Ciba Specialty Chemicals) was dissolved, and the volatile fraction was further removed under a vacuum to obtain the wavelength-converting composition. The solvent content of the wavelength-converting composition was less than 10%. The wavelength-converting composition was found to have flowability both at normal temperature and when heated. The wavelength-converting composition was cured and annealed together with a resin composition prepared by the same method as above except for the absence of the added transparent dispersed solution of compound oxide microparticles prepared in (1), the specific gravity of the cured articles was measured, the residual weight of the cured and annealed wavelength-converting composition was measured subsequent to heating for 1 hour at 400° C., and the oxide microparticle weight fraction was calculated therefrom and found to be 51 vol %.

(3) Evaluations

(3-1) Transparency and Linear Expansion Coefficient The resulting wavelength-converting composition was heated in an oven at a designated temperature (60 to 80° C.), injected into a frame having a thickness of 0.15 mm on a glass plate, and covered from above with a glass plate to fill the frame interior with the wavelength-converting composition. The wavelength-converting composition sandwiched between glass plates obtained in (2) was cured by irradiation with ultraviolet light from both sides at about 500 mJ/cm², and the sheet was peeled off from the glass. The resulting sheet was heated in a vacuum oven for 3 hours at about 100° C., and then for 3 hours at about 275° C. to obtain a sample in the form of a sheet. The thickness of the sheet sample was measured with a micrometer and found to be 141 μm.

Using a thermomechanical analyzer (TMA/SS120C made by Seiko Instruments), the sheet sample was kept for 20 minutes under nitrogen while the temperature was raised from 30° C. to 400° C. at a rate of 5° C. per minute, and the relevant values were measured at a temperature of from 30 to 230° C. The results of measurements taken at a load of 5 g in tensile mode showed the average linear coefficient of expansion to be 39 ppm/° C.

The haze of the sheet sample was measured using a haze meter (NDH2000 made by Nippon Denshoku Industries) and was found to be 0.5; and the collimated beam transmittance was measured using a spectrophotometer (UV-2400PC made by Shimadzu) and was found to be 92%. Examination with the naked eye also revealed the sample to be an extremely transparent sheet.

(3-2) Power Generating Efficiency

Using a spin coater, the wavelength-converting composition prepared in (2) was applied in a dry thickness of about 20 μm to the smooth face of cover glass for a crystalline silicon solar cell. The composition was cured by irradiation with ultraviolet light from both sides at about 500 mJ/cm², and further subjected to a heat treatment for 1 hour at about 200° C. in a vacuum oven. A photovoltaic device was fabricated by the same procedure as in Example 11, and the short-circuit current density differential and conversion efficiency were measured. As a result, it was found that ΔJsc was 0.46 mA/cm² and that the conversion efficiency had improved by 1.5%.

The above evaluations were carried out after the photovoltaic device was allowed to stand outdoors for one month, and no decline in Jsc or conversion efficiency was observed.

The wavelength-converting composition prepared in (2) was applied in a microlens pattern onto the surface of the smooth face of cover glass 8 for a crystalline silicon solar cell using a commercially available inkjet (electrostatic).

The composition was cured by irradiation with ultraviolet light from both sides at about 500 mJ/cm², and further subjected to a heat treatment for 1 hour at about 200° C. in a vacuum oven. Examination with a laser microscope (VK-9700 made by Keyence) revealed that the microlens pattern diameter, height differential of the raised and depressed structures, x-axis direction periodicity, and y-axis direction periodicity were about 30 μm, about 20 μm, about 35 μm, and about 30 μm, respectively. A photovoltaic device was fabricated by the above procedure, and the short-circuit current density differential and conversion efficiency were measured. As a result, it was found that ΔJsc was 0.81 mA/cm² and that the conversion efficiency had improved by 2.7%.

The above evaluations were carried out after the photovoltaic device was allowed to stand outdoors for one month, and no decline in Jsc or conversion efficiency was observed.

The wavelength-converting composition prepared in (2) was mixed with toluene in a 9:1 weight ratio and applied in a microlens pattern onto the surface of the smooth face of cover glass 8 for a crystalline silicon solar cell using a commercially available inkjet (electrostatic). The composition was cured by irradiation with ultraviolet light from both sides at about 500 mJ/cm², and further subjected to a heat treatment for 1 hour at about 200° C. in a vacuum oven. Examination with a laser microscope (VK-9700 made by Keyence) revealed that the microlens pattern diameter, height differential of the raised and depressed structures, x-axis direction periodicity, and y-axis direction periodicity were about 30 μm, about 20 μm, about 35 μm, and about 30 μm, respectively. The surfaces of the top surfaces of the raised and depressed structure were examined with an FE-SEM (JSM-7401F made by JEOL Ltd.), and it was found that a microscopic raised and depressed pattern on the order of several hundred nanometers was observed. A photovoltaic device was fabricated by the above procedure, and the short-circuit current density differential and conversion efficiency were measured. As a result, it was found that ΔJsc was 0.98 mA/cm² and that the conversion efficiency had improved by 3.3%.

The above evaluations were carried out after the photovoltaic device was allowed to stand outdoors for one month, and no decline in Jsc or conversion efficiency was observed.

The wavelength-converting composition prepared in (2) of Example 11 was applied in a microlens pattern onto the surface of a commercially available monocrystalline silicon solar cell using a commercially available inkjet (electrostatic). Microscope examination revealed that the microlens pattern diameter, height differential of the raised and depressed structures, x-axis direction periodicity, and y-axis direction periodicity were about 30 μm, about 10 μm, about 35 μm, and about 30 μm, respectively. The wavelength-converting composition prepared in (2) of Example 12 was then applied thereover in a microlens pattern as shown in FIG. 10, using a commercially available inkjet (electrostatic). The composition was cured by irradiation with ultraviolet light at about 500 mJ/cm², and further subjected to a heat treatment for 1 hour at about 200° C. in a vacuum oven. Examination with a laser microscope (VK-9700 made by Keyence) revealed that the resulting pattern diameter, height differential of the raised and depressed structures, x-axis direction periodicity, and y-axis direction periodicity were about 30 μm, about 20 μm, about 35 μm, and about 30 μm, respectively. A photovoltaic device was fabricated by the above procedure, and the short-circuit current density differential and conversion efficiency were measured. As a result, it was found that ΔJsc was 1.05 mA/cm² and that the conversion efficiency had improved by 3.5%.

The above evaluations were carried out after the photovoltaic device was allowed to stand outdoors for one month, and no decline in Jsc or conversion efficiency was observed.

### Comparative Example 1

Wavelength-converting compositions were prepared by exactly the same procedure as in Example 1, except for modifying the proportions such that the volume fractions of oxide microparticles in the cured wavelength-converting composition were 0, 15, and 33 vol %. The compositions were evaluated for transparency, linear expansion coefficient, and power generating efficiency by the same method as in the Examples. For sheet samples whose oxide volume fractions in the cured wavelength-converting composition were 0, 15, and 33 vol %, the haze was 0.3, 1.0, and 2.5; the collimated beam transmittance was 92, 91, and 89%; and the linear expansion coefficient was 92, 80, and 55 ppm/° C., respectively. Samples whose oxide volume fractions in the cured wavelength-converting composition were 15 and 33 vol % appeared cloudy to the naked eye. None of the fabricated solar cells showed any improvement in power generating efficiency. Solar cells coated with wavelength-converting compositions whose oxide volume fractions in the cured wavelength-converting composition were 15 and 33 vol % had diminished power generating efficiency.

### Comparative Example 2

Wavelength-converting compositions were prepared by exactly the same procedure as in Example 2, except for using proportions such that the volume fractions of oxide microparticles in the cured wavelength-converting composition were 0, 15, and 33 vol %. The compositions were evaluated for transparency, linear expansion coefficient, and power generating efficiency by the same method as in Example 1. For sheet samples whose oxide volume fractions in the cured wavelength-converting composition were 0, 15, and 33 vol %, the haze was 0.4, 1.2, and 2.7; the collimated beam transmittance was 92, 91, and 88%; and the linear expansion coefficient was 92, 80, and 55 ppm/° C., respectively. Samples whose oxide volume fractions in the cured wavelength-converting composition were 15 and 33 vol % appeared cloudy to the naked eye. None of the fabricated solar cells showed any improvement in power generating efficiency. Solar cells coated with wavelength-converting compositions whose oxide volume fractions in the cured wavelength-converting composition were 15 and 33 vol % had diminished power generating efficiency.

### Comparative Example 3

Wavelength-converting compositions were prepared by exactly the same procedure as in Example 8, except for using proportions such that the volume fractions of oxide microparticles in the cured wavelength-converting composition were 0, 15, and 33 vol %. The compositions were evaluated for transparency, linear expansion coefficient, and power generating efficiency by the same method as in Example 1. For sheet samples whose oxide volume fractions in the cured wavelength-converting composition were 0, 15, and 33 vol %, the haze was 0.4, 1.2, and 2.7; the collimated beam transmittance was 92, 91, and 88%; and the linear expansion coefficient was 92, 80, and 55 ppm/° C., respectively. Samples whose oxide volume fractions in the cured wavelength-converting composition were 15 and 33 vol % appeared cloudy to the naked eye. None of the fabricated solar cells showed any improvement in power generating efficiency. Solar cells coated with wavelength-converting compositions whose oxide volume fractions in the cured wavelength-converting composition were 15 and 33 vol % had diminished power generating efficiency.

### Comparative Example 4

Wavelength-converting compositions were prepared by exactly the same procedure as in Example 9, except for using proportions such that the volume fractions of oxide microparticles in the cured wavelength-converting composition were 0, 15, and 33 vol %. The compositions were evaluated for transparency, linear expansion coefficient, and power generating efficiency by the same method as in Example 1. For sheet samples whose oxide volume fractions in the cured wavelength-converting composition were 0, 15, and 33 vol %, the haze was 0.4, 1.3, and 2.9; the collimated beam transmittance was 92, 90, and 87%; and the linear expansion coefficient was 93, 82, and 54 ppm/° C., respectively. Samples whose oxide volume fractions in the cured wavelength-converting composition were 15 and 33 vol % appeared cloudy to the naked eye. None of the fabricated solar cells showed any improvement in power generating efficiency. Solar cells coated with wavelength-converting compositions whose oxide volume fractions in the cured wavelength-converting composition were 15 and 33 vol % had diminished power generating efficiency.

### INDUSTRIAL APPLICABILITY

The present invention is applicable to photovoltaic devices for converting light to electrical energy. Owing to the ability to emit light of wavelengths in the visible region in response to the application of voltage, to irradiation with an electron beam, or to the ultraviolet or infrared radiation in sunlight, the invention is also suitable for use in fields such as bio-imaging, security coatings, displays, illumination, and the like. The wavelength-converting composition can itself be used as photovoltaic device in cases in which nanocrystals are used as such a composition.

1. A wavelength-converting composition comprising:
a curing resin; and
a wavelength-converting substance for converting a wavelength of absorbed light.

2. The wavelength-converting composition according to claim 1, comprising:
oxide microparticles; and
the wavelength-converting substance being contained in the oxide microparticles.

3. The wavelength-converting composition according to claim 2, comprising the oxide microparticles in an amount of 40 to 60 vol %.

4. The wavelength-converting composition according to claim 2, wherein the oxide microparticles have a mean particle diameter of 20 to 100 nm.

5. The wavelength-converting composition according to claim 2, wherein the oxide microparticles have a mean particle diameter of 45 to 55 nm.

6. The wavelength-converting composition according to claim 2, wherein the oxide microparticles are silica or zirconia microparticles.

7. The wavelength-converting composition according to claim 2, wherein the oxide microparticles are YVO₄ or Y₂O₃ microparticles.

8. The wavelength-converting composition according to claim 7, comprising bismuth (Bi).

9. The wavelength-converting composition according to claim 1, wherein the wavelength-converting substance is a substance containing one, or two or more elements selected from the group consisting of europium (Eu), erbium (Er), dysprosium (Dy), and neodymium (Nd).

10. The wavelength-converting composition according to claim 1, wherein the wavelength-converting substance is semiconductor microparticles.

11. The wavelength-converting composition according to claim 10, wherein the semiconductor microparticles are silicon (Si).

12. The wavelength-converting composition according to claim 10, wherein the semiconductor microparticles are zinc oxide (ZnO).

13. A wavelength-converting layer formed by curing a layer of the wavelength-converting composition according to claim 1.

14. A photovoltaic device comprising the wavelength-converting layer according to claim 13.

15. The photovoltaic device according to claim 14, wherein the wavelength-converting layer has a raised and depressed structure in a plane of the photovoltaic device.

16. The photovoltaic device according to claim 15, wherein the raised and depressed structure has a height differential of 300 nm to 100 μm.

17. The photovoltaic device according to claim 16, wherein the raised and depressed structure has an in-plane periodicity of 300 nm to 50 μm.

18. The photovoltaic device according to claim 15, wherein the raised and depressed structure has an even smaller raised and depressed sub-pattern.

19. The photovoltaic device according to claim 15, comprising laminated wavelength-converting layers having two or more different types of raised and depressed structures.

20. The photovoltaic device according to claim 13, wherein the wavelength-converting layer is formed by an inkjet.

21. The photovoltaic device according to claim 20, wherein the inkjet is a piezo inkjet.
